(19) United States
(12) Patent Application Publication
(10) Pub. No.: US 2006/0091513 A1
(43) Pub. Date: May 4, 2006

(54) Chip package having flat transmission surface of transparent molding compound and method for manufacturing the same

(76) Inventor: Gwo-Liang Weng, Kaoshiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/263,975

(22) Filed: Nov. 2, 2005

(30) Foreign Application Priority Data
Nov. 3, 2004 (TW) 093133486

(51) Int. Cl. H01L 23/02

(52) U.S. Cl. 257/678

(57) ABSTRACT

A chip package having flat transmission surface of transparent molding compound mainly comprises a substrate, a chip, a transparent cover and a transparent molding compound. The transparent molding compound is formed between the substrate and the transparent cover to seal the chip. The transparent molding compound is tightly attached to the transparent cover to form a flat transmission surface.

### BACKGROUND OF THE INVENTION

1. Field of the Invention

The present invention relates to a chip package having an image sensor, and more particularly to a chip package having flat transmission surface of transparent molding compound and the method for manufacturing the same.

2. Description of the Related Art

A conventional image sensor package comprises an optical semiconductor chip with image sensing function, such as a complementary metal oxide semiconductor (CMOS) chip or a charge coupled device (CCD) chip. The image sensor chip comprises an image sensing area which is rather sensitive. Accordingly, the formation quality of the transparent molding compound for packaging the image sensor chip is extremely important. In addition to protecting the image sensing area from outside pollution of dusts and vapors, the transparent molding compound is also required to have a flat transmission surface so that it will not affect the incident light of the light source of product.

Referring to FIG. 1A, a conventional chip package 100 having an image sensor chip comprises a substrate 110. A chip 120 is disposed on an upper surface 111 of the substrate 110. The chip 120 comprises an active surface 121 and a non-active surface 122. The active surface 121 has an image sensing area 123. The non-active surface 122 is adhered to the upper surface 111 of the substrate 110 by an adhesive layer 125, such as glue or an adhesive tape. A plurality of bonding wires 130 connect a plurality of bonding pads 124 on the chip 120 and a plurality of connecting pads 112 on the substrate 110. A transparent molding compound 140 is formed on the upper surface 111 of the substrate 110 to seal the chip 120 and the bonding wires 130. Usually, the transparent molding compound 140 is formed by transfer molding and has an exposed compound surface 141. Because the transparent molding compound 140 is formed by transfer molding, the compound surface 141 is easily uneven due to poor cleanness of the cavity of a mold, which affects the transmittance of the transparent molding compound 140. Furthermore, the compound surface 141 of the transparent molding compound 140 is an exposed surface, so it is easily scratched, and thus affects the quality of sensing.

Referring to FIG. 2, the conventional manufacturing method of the chip package 100 is shown. First, the substrate 110 having the chip 120 and the bonding wires 130 are disposed in a cavity 311 of a mold 310, and the inner surface of the cavity 311 is designed as a mirror. Then the cavity 311 is filled up with a transparent compound to form the transparent molding compound 140. Due to the close contact of the transparent molding compound 140 to the inner surface of the mold 310, it is necessary to keep cleanness of the inner surface of the mold 310 to avoid unevenness of the surface 141 of the transparent molding compound 140 after releasing the mold 310, and affecting the transmittance of the transparent molding compound 140. Furthermore, the inner surface of the cavity 311 is of a mirror design and is not allowed to be contaminated by dust. But the mold 310 will have residua after continuous moldings. To keep it clean is not easy. In order to maintain the inner surface of the mold 310 clean, it is necessary to clean the inner surface of the mold 310 frequently, but the surface is extremely easy to be worn, torn or scratched, which results in unevenness of the surface 141 of the transparent molding compound 140 after releasing the mold 310.

Consequently, there is an existing need for a chip package having flat transmission surface of transparent molding compound and the method for manufacturing the same to solve the above-mentioned problems.

### SUMMARY OF THE INVENTION

The object of the present invention is to provide a chip package having flat transmission surface of transparent molding compound. A transparent cover is disposed on an upper surface of a substrate. A transparent molding compound is formed between the substrate and the transparent cover to seal a chip. The transparent molding compound is tightly attached to the transparent cover to form a flat transmission surface. Furthermore, the transparent cover is used to protect the flat transmission surface from being scratched.

Another object of the present invention is to provide a manufacturing method of a chip package having flat transmission surface of transparent molding compound. The manufacturing method of the present invention comprises the steps of: first, providing a substrate strip having a plurality of substrates; then providing at least one transparent cover on an upper surface of the substrates; afterwards disposing the substrate strip into a cavity of a mold and then filling the cavity with a transparent molding compound so as to form a transparent molding compound between the upper surfaces of the substrates and the transparent cover of hard material. The manufacturing method of the present invention can avoid that the transparent molding compound contacting the inner surface of the cavity of the mold.

Still another object of the present invention is to provide a manufacturing method of a chip package having flat transmission surface of transparent molding compound. A release film is formed on the transparent cover so as to make the release film contact the inner surface of the mold cavity and to avoid the transparent cover contacting directly to the mold. The release film can be removed from the transparent cover after finishing the molding package.

The chip package having flat transmission surface of transparent molding compound according to the present invention comprises a substrate, a chip, a transparent cover and a transparent molding compound. The substrate has an upper surface. The chip is disposed on the upper surface of the substrate. The transparent cover is disposed on the upper surface of the substrate. The transparent molding compound is formed between the substrate and the transparent cover to seal the chip. The transparent molding compound is tightly attached to the transparent cover to form an unexposed flat transmission surface.

### BRIEF DESCRIPTION OF THE DRAWINGS

FIG. 1 is a schematic cross-sectional view of a conventional chip package;

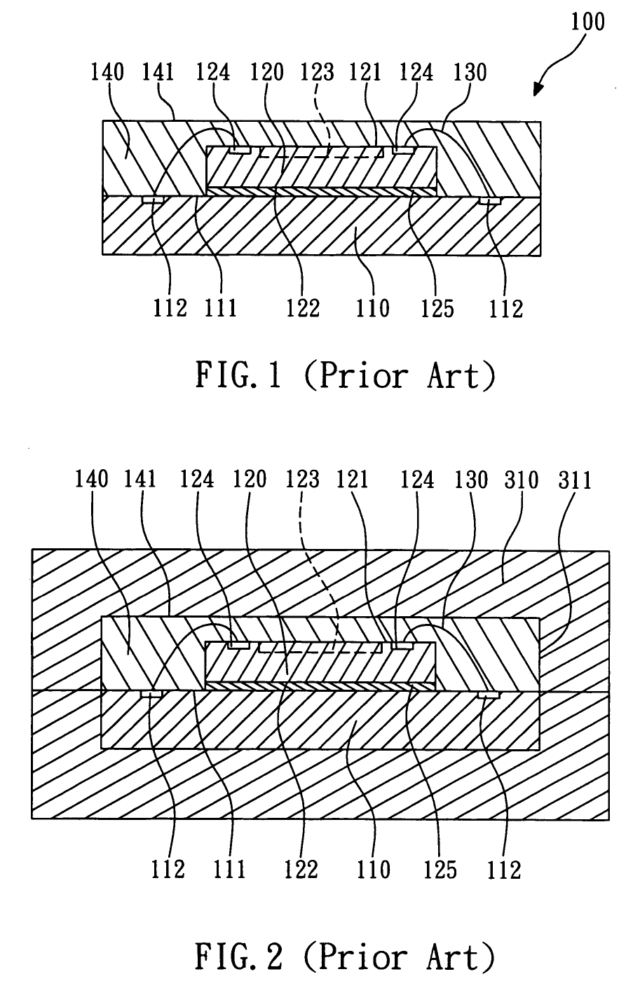

FIG. 2 is a schematic cross-sectional view of a conventional chip package when forming a transparent molding compound;

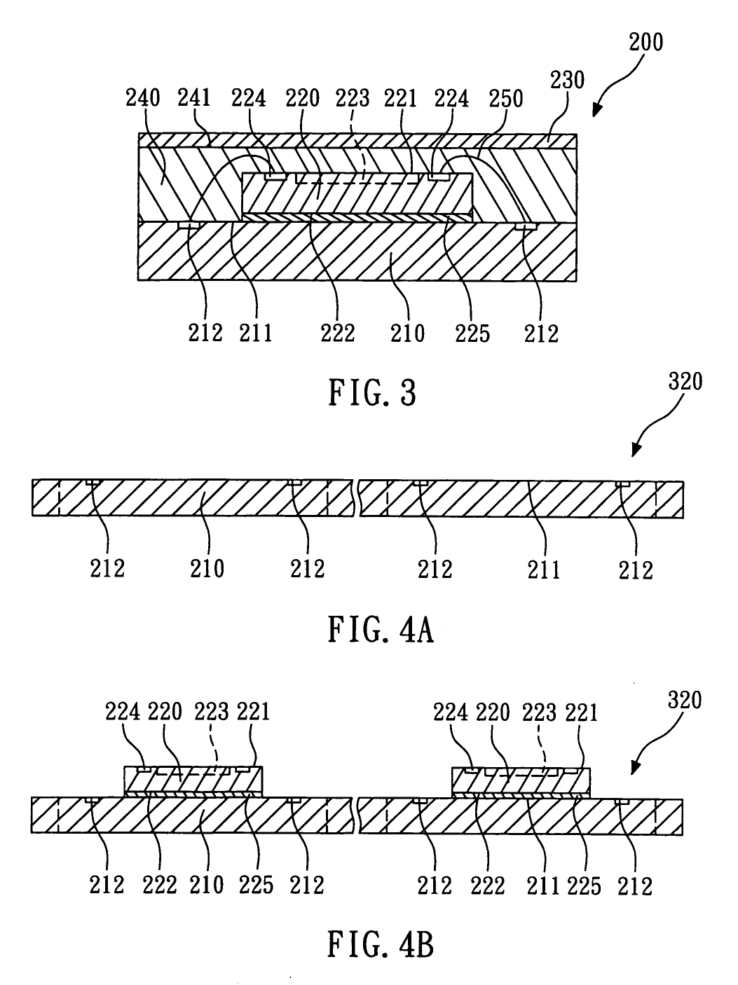

FIG. 3 is a schematic cross-sectional view of a chip package having flat transmission surface of transparent molding compound according to an embodiment of the present invention; and

FIGS. 4A to 4G are schematic cross-sectional views for illustrating a method for manufacturing the chip package according to an embodiment of the present invention.

### DETAILED DESCRIPTION OF THE INVENTION

The present invention will be described by the following embodiment referring to the accompanying drawings.

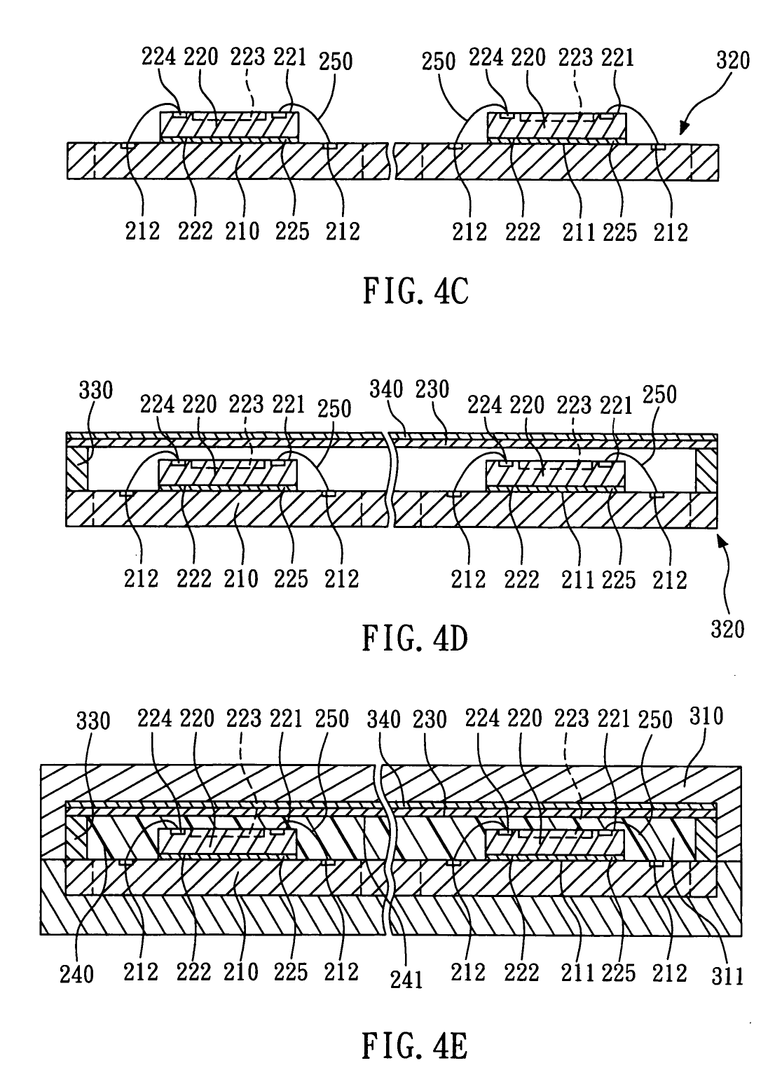

Referring to FIG. 3, according to an embodiment of the present invention, a chip package 200 comprises a substrate 210, a chip 220, a transparent cover 230 and a transparent molding compound 240. The substrate 210 has an upper surface 211 and comprises a plurality of connecting pads 212 formed on the upper surface 211. The substrate 210 may be a printed-circuit board, a leadframe or other chip loading boards.

The chip 220 has an active surface 221 and a non-active surface 222 adhered to the upper surface 211 of the substrate 210 by an adhesive layer 225. In the embodiment, the chip 220 is an image sensor chip, for example, a complementary metal oxide semiconductor (CMOS) chip or a charge coupled device (CCD) chip. The chip 220 comprises an image sensing area 223 on the active surface 221. A plurality of bonding wires 250 are electrically connected to a plurality of bonding pads 224 of the chip 220 and the connecting pads 212 of the substrate 210.

The transparent cover 230 is disposed above the upper surface 211 of the substrate 210 and faces the active surface 221 of the chip 220. The transparent cover 230 can be a sheet of glass or acryl.

The transparent molding compound 240 is formed between the upper surface 211 of the substrate 210 and the transparent cover 230 to seal the chip 220 and the bonding wires 250. The transparent molding compound 240 is tightly attached to the transparent cover 230 to form a flat transmission surface 241. Preferably, the transparent cover 230 is parallel to the upper surface 211 of the substrate 210 and the active surface 221 of the chip 220 to improve the quality of the chip package 200 having extremely high sensitivity.

In the chip package 200, the transparent cover 230 is on the transparent molding compound 240. The transparent molding compound 240 is tightly attached to the transparent cover 230 so as to form the flat transmission surface 241 and to avoid the flat transmission surface 241 being scratched.

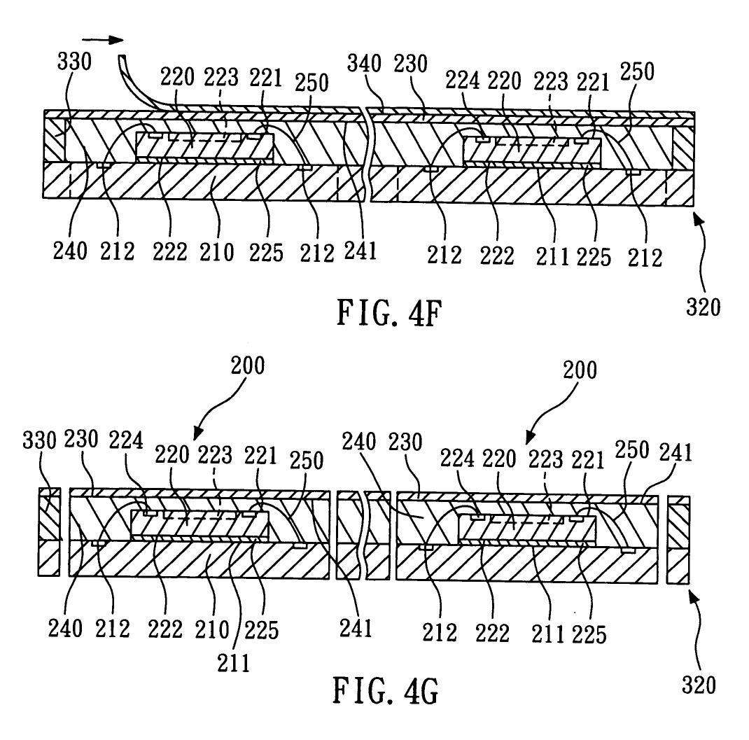

Referring to FIGS. 4A to 4G, according to the present invention, the manufacturing method of the chip package having flat transmission surface of transparent molding compound is described. Referring to FIG. 4A, first, a substrate strip 320 is provided. The substrate strip 320 comprises a plurality of substrates 210. The substrates 210 have an upper surface 211 and a plurality of connecting pads 212 formed on the upper surface 211.

Referring to FIG. 4B, a plurality of chips 220 are disposed on the upper surfaces 211 of the substrates 210. Each of the chips 220 has an active surface 221 and a non-active surface 222. The non-active surface 222 of the chip 220 is adhered to the upper surface 211 of the substrate 210. In the present embodiment, the chips 220 are the image sensor chips and include an image sensing area 223 disposed on the active surface 221.

Referring to FIG. 4C, a plurality of bonding wires 250 are formed and are used to electrically connect a plurality of bonding pads 224 of the chip 220 and the connecting pads 212 of the substrates 210.

Referring to FIG. 4D, preferably, a spacing board 330 is disposed on the substrate strip 320. Then at least one transparent cover 230 is provided on the spacing board 330 so that the transparent cover 230 is disposed above the upper surfaces 211 of the substrates 210. The spacing board 330 can position the transparent cover 230 before molding and make a fixed spacing distance between the transparent cover 230 and the substrates 210, wherein the active surfaces 211 of the chips 220 face the transparent cover 230. In the present embodiment, a release film 340 is formed on the transparent cover 230 for releasing easily and avoiding the transparent cover 230 of hard material contacting directly to a mold 310 (FIG. 4E).

Referring to FIG. 4E, in the present embodiment, the substrate strip 320 having the chips 220, the transparent cover 230, the bonding wires 250 and the spacing board 330 is disposed into a cavity 311 of a mold 310. The release film 340 contacts the top inner surface of the cavity 311 to avoid the transparent cover 230 contacting the mold 310 directly. Then, a transparent molding compound 240 is formed between the substrates 210 and the transparent cover 230 to seal the chips 220 and the bonding wires 250. After being formed, the transparent molding compound 240 is tightly adhered to the transparent cover 230 and has a flat transmission surface 241. Referring to FIG. 4F, after the substrate strip 320 is released from the mold 310, the release film 340 is removed and the transparent cover 230 is exposed. Because the transparent cover 230 is disposed between the release film 340 and the transparent molding compound 240, and the binding force between the transparent cover 230 and the release film 340 is weak, the release film 340 can be easily taken off without damaging the transparent cover 230 and transparent molding compound 240.

Referring to FIG. 4G, the substrates 210 are singulated. In the present embodiment, the substrate strip 320, the transparent cover 230 and the transparent molding compound 240 can be cut off by sawing so as to separate the substrates 210 and to form a plurality of chip packages 200. Accordingly, as shown in FIG. 3, a side of the substrate 210 and a side of the transparent molding compound 240 are on the same cutting surface.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

What is claimed is:

1. A chip package having flat transmission surface of transparent molding compound, comprising:
a substrate having an upper surface;
a chip disposed on the upper surface of the substrate;
a transparent cover disposed above the upper surface of the substrate; and
a transparent molding compound formed between the substrate and the transparent cover to seal the chip, wherein the transparent molding compound is tightly attached to the transparent cover to form a flat transmission surface.

2. The chip package having flat transmission surface of transparent molding compound according to claim 1, wherein the chip is an image sensor chip.

3. The chip package having flat transmission surface of transparent molding compound according to claim 1, wherein the transparent cover is a sheet of glass.

4. The chip package having flat transmission surface of transparent molding compound according to claim 1, wherein the transparent cover is a sheet of acryl.

5. The chip package having flat transmission surface of transparent molding compound according to claim 1, further comprising a plurality of bonding wires electrically connected to the chip and the substrate.

6. The chip package having flat transmission surface of transparent molding compound according to claim 1, wherein the transparent cover is parallel to an active surface of the chip.

7. The chip package having flat transmission surface of transparent molding compound according to claim 6, wherein the active surface of the chip faces the transparent cover.

8. A method for manufacturing a chip package, comprising:
providing a substrate strip, the substrate strip having a plurality of substrates, each of the substrates having an upper surface;
disposing a plurality of chips on the upper surfaces of the substrates;
providing at least one transparent cover on the upper surfaces of the substrates; and
forming a transparent molding compound between the upper surface of the substrate and the transparent cover to seal the chips, wherein the transparent cover is tightly attached to the transparent cover to form a flat transmission surface.

9. The method according to claim 8, after forming the transparent molding compound, further comprising:
singulating the substrates to form a plurality of chip packages.

10. The method according to claim 9, wherein the singulating method is sawing, and the transparent molding compound is sawed while the substrate strip is being sawed.

11. The method according to claim 10, wherein a side of the substrate and a side of the transparent molding compound are on the same cutting surface.

12. The method according to claim 8, wherein in the step of forming the transparent molding compound, a release film is formed on the transparent cover and removed after the transparent molding compound is formed.

13. The method according to claim 8, after disposing the chips, further comprising:
disposing a spacing board on the substrate strip to position the transparent cover so as to form a fixed spacing between the transparent cover and the substrate.

14. The method according to claim 8, wherein the chip is an image sensor chip.

15. The method according to claim 8, wherein the transparent cover is a sheet of glass.

16. The method according to claim 8, wherein the transparent cover is a sheet of acryl.

17. The method according to claim 8, after disposing the chips, further comprising:
forming a plurality of bonding wires to electrically connect the chips and the substrates.

18. The method according to claim 8, wherein the transparent cover is parallel to an active surface of the chip.

19. The method according to claim 18, wherein the active surface faces the transparent cover.
